(19) United States
(12) Patent Application Publication
(10) Pub. No.: US 2010/0136232 A1
(43) Pub. Date: Jun. 3, 2010

(54) CURING OF POLYMER COMPOSITES

(76) Inventors: Laurence John Walker, Malaga (AU); Michael Alex Haywood, Malaga (AU); Jason Ian Lecoultre, Malaga (AU); Gregory James Millen, Malaga (AU)

Correspondence Address: NEIFELD IP LAW, PC, 4813-B EISENHOWER AVENUE, ALEXANDRIA, VA, 22304, US

(21) Appl. No.: 12/593,687

(22) PCT Filed: Mar. 28, 2008
(86) PCT No.: PCT/AU2008/000444

§ 371 Date: Nov. 27, 2009

(30) Foreign Application Priority Data
Mar. 30, 2007 (AU) 2007901696

(51) Int. Cl. C23C 16/44; C23C 16/00; C23C 16/52

(52) U.S. Cl. 427/248.1; 118/715; 118/667

(57) ABSTRACT

There is provided an apparatus (2) for the forming or curing of a fibre-reinforced polymer composite material (10). The apparatus (2) comprises a first layer of material (4) positioned to overly the fibre-reinforced polymer (10); a second layer of material (6) positioned to overly the first layer (4) to define a chamber (8) therebetween. The apparatus (2) further comprises a vapour source (16) and a fluid communication path having; a transfer section (18) in fluid communication with the vapour source (16) and chamber (8), and, a return section (20) in fluid communication with the chamber (8) and the vapour source (16).

### FIELD OF THE INVENTION

The present invention relates to an apparatus and a method for forming or curing composite materials.

### BACKGROUND OF THE INVENTION

The term “composite materials” generally refers to materials produced by curing fibrous materials within a matrix of a resinous substrate. Composite materials are used in a variety of industries ranging from aerospace, motor sports, automotive, boating and construction. Composite materials are formed from, or comprise, a composition of a plurality of individual layers called laminates. The fibrous materials used in composite products vary markedly and often include carbon, aramid and glass fibres. In some instances the fibres are of a polymer nature. The resinous substrates, or matrix materials, are generally selected from either thermoplastic or thermosetting resins such as epoxy, cyanate, phenolic and other like and/or similar products.

The components of a polymer composite are generally formed or cured under conditions of elevated temperature and pressure. The combination of pressure and temperature enables the resin to form around the fibres to form the composite to a desired shape and integrity.

In the field of civil engineering, infrastructure construction and repair, the quality requirements of polymer composite structures are similar to those required by the aerospace industry. By contrast, however, the size of structures and the necessity for on-site repair and manufacture have excluded the use of aerospace quality composite materials. Recently, significant numbers of repairs to bridges, buildings, dams and other concrete and steel structures have been undertaken. These repairs have focused on the use of weak layer or secondarily bonded carbon fibre/epoxy composite systems. These weak layers, or secondary bonded systems, have been found to produce poor-quality final bond strengths and unreliable repairs.

It will be clearly understood that, although prior art use and publications are referred to herein, this reference does not constitute an admission that any of these form a part of the common general knowledge in the art, in Australia or in any other country.

### SUMMARY OF THE INVENTION

In the statement of invention and description of the invention which follow, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

According to a first aspect of the present invention, there is provided an apparatus for the forming or curing of a fibre-reinforced polymer composite material comprising:
a first layer of material overlying the fibre-reinforced polymer;
a second layer of material overlying said first layer to define a chamber therebetween;
a vapour source;
a fluid communication path having:
   (i) a transfer section in fluid communication with said vapour source and said chamber; and,
   (ii) a return section in fluid communication with said chamber and said vapour source.

The communication path may be configured to release vapour and/or condensate of said vapour to the atmosphere.

The transfer section may comprise at least one transfer conduit through which said vapour can flow from said vapour source to said chamber.

The return section may comprise at least one return conduit through which said condensate and/or said vapour can flow from said chamber to said vapour source.

In one embodiment, the second layer is affixed to said first layer to define said chamber. In this embodiment, the said second layer may be affixed by being heat sealed to said first layer. Alternatively, the second layer may be affixed by being mechanically fastened to the first layer. Furthermore, the second layer may be affixed by being chemically and/or mechanically bonded to the first layer in either a permanent and/or semi-permanent manner.

One or both of the first and second layers may comprise an air-tight material.

In addition, or alternatively, one or both of the first and second layers may comprise a material of limited extensibility.

In addition, or alternatively, one or both of the first or second layers may comprise either pliable or rigid materials.

In one embodiment, the first and/or second layer may comprise a thermally responsive material, such as, for example, a “shrink” film.

The apparatus may further comprise a vacuum device coupled to establish a vacuum between said first layer and said polymer.

In this embodiment the apparatus may further comprise at least one air exhaust conduit providing fluid communication from a region between said first layer and said polymer and said vacuum device to exhaust air from within said chamber.

The apparatus may further comprise a first pump coupled to said return conduit to pump condensate and/or said vapour from said chamber to said vapour source.

The apparatus may, in addition or alternatively, comprise a second pump coupled to said transfer conduit to pump said vapour from said vapour source to said chamber.

At least one temperature sensing device may be positioned adjacent or proximal said polymer or within said communication path to measure temperature.

A flow rate regulator, operatively associated with at least a first of the temperature sensing devices, may be provided to regulate the flow rate of vapour through said fluid communication path.

A vapour temperature regulator, operatively associated with at least a second of the temperature sensing devices, may be provided to regulate the temperature of said vapour within said fluid communication path.

A vapour temperature regulator, operatively associated with at least a second of the temperature sensing devices, may be provided to regulate the Dryness factor of said vapour within said fluid communication path.

In yet a further embodiment, the transfer and return conduits and said chamber are relatively juxtaposed one another so as to encourage a flow of said vapour through said chamber.

According to a second aspect of the present invention, there is provided a method for the forming or curing of a fibre-reinforced polymer composite comprising the steps of:
(i) laying up an uncured fibre-reinforced polymer;
(ii) overlaying said polymer with a first flexible layer of material;
(iii) overlaying said first layer of material with a second layer of material so as to define a chamber therebetween;
(iv) filling said chamber with a heated vapour from a vapour source in fluid communication with said chamber; and,
(v) returning at least a portion of said vapour and/or condensate of said vapour to said vapour source.

In one embodiment, the method further comprises the step of applying a vacuum to a region between said polymer and said first layer of material.

In the same or an alternative embodiment, the method further comprises the step of providing a transfer conduit in fluid communication with said vapour source and said chamber whereby said vapour is transferred from the vapour source to said chamber.

The method may further comprise the step of providing a return conduit in fluid communication with said vapour source and said chamber to return said vapour and/or condensate of said vapour to said vapour source.

The method may further comprise the step of applying a first vacuum pressure vacuum between the first and second layer to remove air from the chamber and/or vapour source prior to admitting said vapour.

The method may further comprise the step of applying a second vacuum pressure vacuum via said return conduit for inducing or facilitating a flow of said vapour and/or condensate of said vapour from said chamber to said vapour source.

The method may further comprise the step of applying a second vacuum pressure, after application of the first vacuum pressure, via said return conduit for inducing or facilitating a flow of said vapour and/or condensate of said vapour from said chamber to said vapour source.

The method may further comprise the step of applying the second vacuum pressure within said transfer conduit for inducing or facilitating a flow of said vapour and/or condensate of said vapour source to said chamber.

In one embodiment of the method, the first vacuum pressure is greater than the second vacuum pressure.

The method may further comprise the step of applying pressure to said vapour in said transfer conduit to change the thermal characteristics of said vapour.

In yet a further embodiment, the method further comprises the step of applying a pressure differential within said transfer conduit for inducing or facilitating a flow of said vapour and/or condensate of said vapour source to said chamber.

In another embodiment, step (v) of the method may comprise the step of:
(v) returning all said vapour and/or condensate to the atmosphere, or, at least a portion of said vapour and/or condensate of said vapour to said vapour source.

In still a further embodiment, the method further comprises the step of applying pressure to said vapour in said transfer conduit to change the thermal characteristics of said vapour.

In one embodiment the step of laying up of an uncured fibre-reinforced polymer is conducted in situ.

### BRIEF DESCRIPTION OF THE DRAWINGS

The preferred embodiments of the present invention will now the described, by way of example only, with reference to the accompanying drawings, in which:

FIG. 1 shows a schematic view of one embodiment of the present invention;

FIG. 2 shows a schematic view of a further embodiment of the present invention;

FIG. 3 shows a schematic view of still a further embodiment of the present invention;

FIG. 4 shows a schematic view of yet a further embodiment of the present invention;

FIG. 5 shows a diagrammatic view of a further embodiment of the present invention;

FIG. 6 shows a schematic view of a further embodiment of the present invention;

FIG. 7 shows a schematic view of yet a further embodiment of the invention;

FIG. 8 shows a schematic view of a further embodiment of the present invention incorporating the temperature sensing devices;

FIG. 9 shows a diagrammatic view of a further embodiment of the present invention used in the reinforcement of the underside of a channel section structure;

FIG. 10 shows a diagrammatic detail view of an aspect as identified in FIG. 9;

FIG. 11 shows a diagrammatic detail view of an aspect as identified in FIG. 9;

FIG. 12 shows a diagrammatic view of the apparatus shown in FIG. 9 further incorporating temperature sensing devices;

FIG. 13 shows a diagrammatic view of yet a further embodiment of the present invention; and,

FIG. 14 shows a schematic perspective view of another embodiment in accordance with the present invention.

### DETAILED DESCRIPTION OF THE PREFERRED EMBODIMENTS OF THE INVENTION

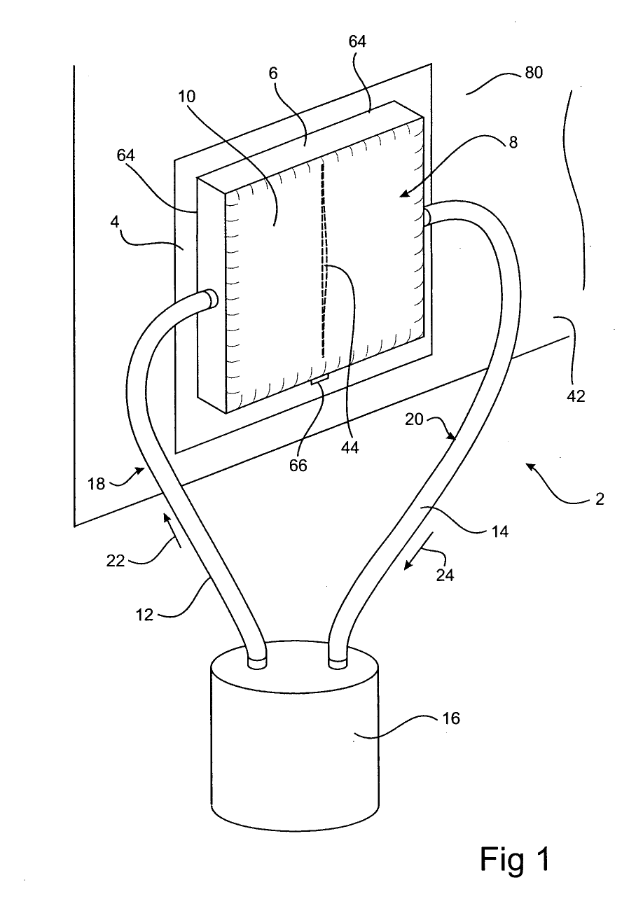

FIG. 1 shows one embodiment of an apparatus 2 in accordance with the present invention used for the forming or curing of a composite material 10. The apparatus 2 comprises a first layer of material 4 placed adjacent or proximal the composite material 10. Generally, the first layer of material 4 is placed in such a manner so as to completely cover or overlay the composite material 10 that is to be cured.

The first layer of material 4 may be suitably selected to have sufficient pliability so as to cover composite laminations. Thus the shape and configuration of the first layer 4 is determined by the particular application at hand and is otherwise immaterial to the invention. In most instances, the first layer material 4 will have sufficient strength, thermal and other physical properties to provide an adequate barrier protecting the composite material 10 from exposure to moisture during the curing process. Further, the first layer of material 4 also protects the surface 80 of the structure 42 from corrosion due to moisture. The first layer of material 4 will be of sufficient strength to be able to withstand application of a negative pressure environment when a vacuum is applied between the composite material 10 and the first layer of material 4 and possess suitable thermodynamic properties to transfer heat to the composite material 10 and/or suitable thermodynamic properties to transfer heat during the curing process.

The composite material 10 is placed over a surface 80 of a work structure 42 that is to be reinforced or repaired. Furthermore, the composite material 10 may be positioned over a defect in a work surface 80 of the structure 42 such as a crack 44 for the purposes of providing sufficient reinforcement to improve the structural integrity of the structure 42. It may be appreciated that surface 80 may comprise a previously cured composite material placed or cured upon work structure 42 over which the composite material 10 is placed. The composite material 10 may comprise a composite of at least one layer of a fibrous material. Each layer may comprise a plurality of woven fibres orientated in any number of directions depending upon specific structural requirements. Examples of fibrous materials may include carbon, aramid (Kevler™) and fibreglass. Many other possible fibres and/or blends of composite fibres known to those skilled in the art may be used in any of the embodiments of the present invention described herein.

Formation of the composite material prior to curing further requires the composition (layer or layers) of fibres to be impregnated or surrounded within a matrix material such as a resinous substance (“resin”). In some instances, each individual layer may be pre-impregnated with a resin. This is referred to as “pre-preg”. In other instances, a plurality of layers is stacked, with each layer being saturated with resin when being placed in position. This process is referred to as a “wet lay-up”. Moreover, alternative resin application processes such as “resin infusion” are used prior to curing to apply or distribute the resin around the fibre layers. All such methods of composing the composite material and resin application upon a work surface 80 may be used with all embodiments of the present invention described herein. Furthermore, any pre-cured composite may also be used in conjunction with any of the later described processes for composing or “laying up” a composite material 10 to be cured. It may also be appreciated that all embodiments of the present invention described herein may be used in conjunction with any size or dimension of a surface 80 of a work structure 42. It may be appreciated that the first layer of material 4 may comprise of one or more layers of a material to achieve the sufficient strength and thermodynamic characteristics required.

A second layer of material 6 overlays the first layer of material 4 in such a way so as to define a chamber 8 which covers, at least all of the composite material 10 to be cured. The chamber 8 is configured to generally contain a vapour and to be capable of conforming to large complex parts such as, for example, component parts for buildings, bridges or aircraft.

The chamber 8 is generally formed by the second layer of material 6 being attached to the first layer of material 4 at sealed joins 64 such that the chamber 8 defines a generally closed or sealed environment. The joins 64 may be formed using an adhesive to chemically or mechanically bond the layers 4 and 6 or by a heat seal or other like sealing process known to one skilled in the art. It may be appreciated, however, that other methods of defining the chamber may be readily discernable to one skilled in the art.

Such methods may comprise the use of mechanical fasteners to fasten the second layer of material to the first layer of material. A further embodiment may comprise the second layer of material being of a rigid nature that could be bolted or screwed either directly or indirectly (using any intermediate member) to the first layer of material.

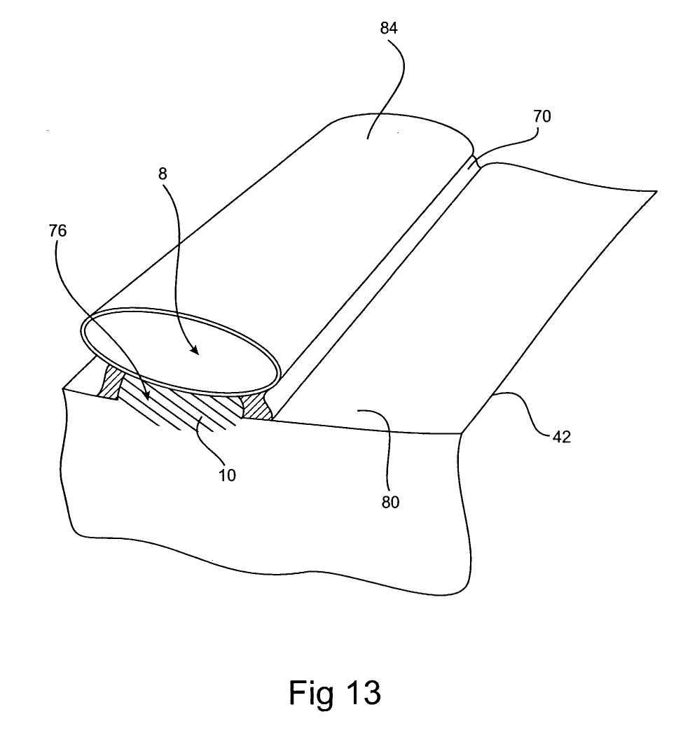

Furthermore, the chamber may comprise a hollow cylindrical member (e.g. such as a tube 84 or the like) that may be fixed or fastened to the first layer of material (shown in FIG. 13). It may also be recognised that the cylindrical member may be constructed from, or comprise, a material, or composition of materials, that are able to achieve, individually or collectively, a pliable or flexible form so as to be able to conform to a non-uniform or complex surface geometry to which a repair or reinforcement, using composite material 10, is to be applied.

The chamber 8 is configured so as to be in fluid communication with a vapour source 16. The vapour source generates heated vapour that is transferred to the chamber 8 by a transfer section 18 which is in fluid communication with both the chamber 8 and vapour source 16. The transfer section 18 may comprise a transfer conduit 12 through which vapour enters the chamber 8. Vapour fills the chamber 8 so that an even distribution of heat can be achieved within the chamber 8 for curing the composite material 10 at generally atmospheric pressure. As the vapour continues to enter chamber 8, the thermodynamic transfer of heat to the composite material 10 for curing increases. It will be appreciated by one skilled that the latent heat of vaporisation and condensation inherently controls the temperature around the condensation (dew) point of the vapour.

The second layer of material 6 may comprise a pliable material or a rigid material. In some instances, the second layer of material 6 may be inextensible, but of sufficient integrity to tolerate the temperatures and possible pressures required for curing. The chamber 8 is formed by the first 4 and second 6 layer of material may be a sacrificial component and discarded after the curing process. Alternatively, however, it may be a reusable component, depending upon the nature of the repair.

In some cases, it may be advantageous to initially evacuate substantially all the air from the chamber 8 prior to the admission of vapour from the vapour source 16. By applying an initial vacuum to the chamber 8, air may be removed so that admission of vapour from the vapour source 16 provides an immediate temperature change and is not delayed by the cooling effect that will occur if ambient air is initially present in the chamber 8.

Vapour and/or condensate may exit the chamber 8 through a return section 20, which is in fluid communication with the vapour source 16 and the chamber 8. Vapour and/or condensate may therefore return to the vapour source 16 in a return direction 24 so as to establish a recirculated flow through the chamber 8. The return section 20 may be useful in instances where, for example, the cure of a composite material 10 is to take place in an area or environment where moisture is to be avoided due to nearby electrical equipment, house or office furniture or other like equipment that may be sensitive to moisture.

The return section 20 may comprise a return conduit 14 through which vapour flows from the chamber 8 back to the vapour source 16. Furthermore, as the vapour cools and condenses, condensate may form within the return conduit 14 and, depending upon the orientation of the apparatus 2 and return conduit 14, may drip back into the vapour source 16 by action or gravity. It may be appreciated that the vapour emitted from the vapour source 16 through the transfer conduit 12 may also cause some condensation to occur within the transfer conduit 12 and drip/return back to the vapour source 16 by gravity.

Both the transfer 12 and return conduits 14 may be made from any material with suitable thermal properties for transferring vapour efficiently between the chamber 18 and the vapour source 16, respectively. Further, to reduce the risk of condensation forming, transfer conduit 12 may be configured with an appropriate heating device so as to maintain a heated condition during operation. Transfer conduit 12 may comprise resistance wire wound peripherally within or about each conduit for heating the conduits. The heating effect provided by the wire, or conduit heating device, may be regulated by a controller that receives temperature measurements from thermocouples located within each conduit, the vapour 16, the chamber 8 or proximal the curing composite material 10 so as to maximise vapour content within the system and minimise condensate forming. The chamber 8 may also comprise a similar heating device or wire to sufficiently heat the second layer of material 6 so as to reduce condensate forming and maximise residence time of the vapour within the chamber 8.

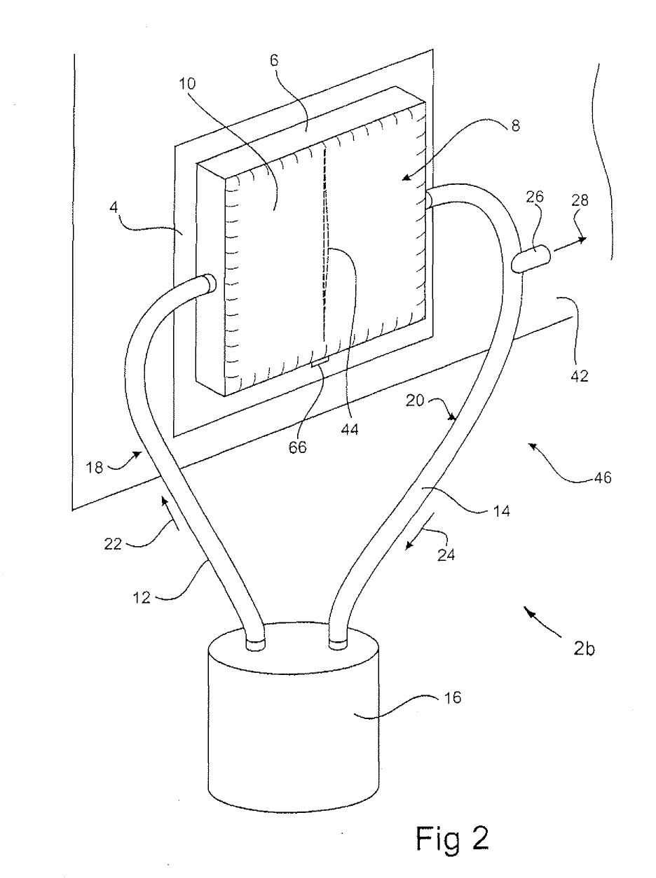

An apparatus 2b in accordance with a further embodiment of the present invention is shown in FIG. 2. The apparatus 2b retains any or all of the prior features described for apparatus 2 and further includes a release valve 26 whereby the vapour may be exhausted directly to the atmosphere upon exiting the chamber 8.

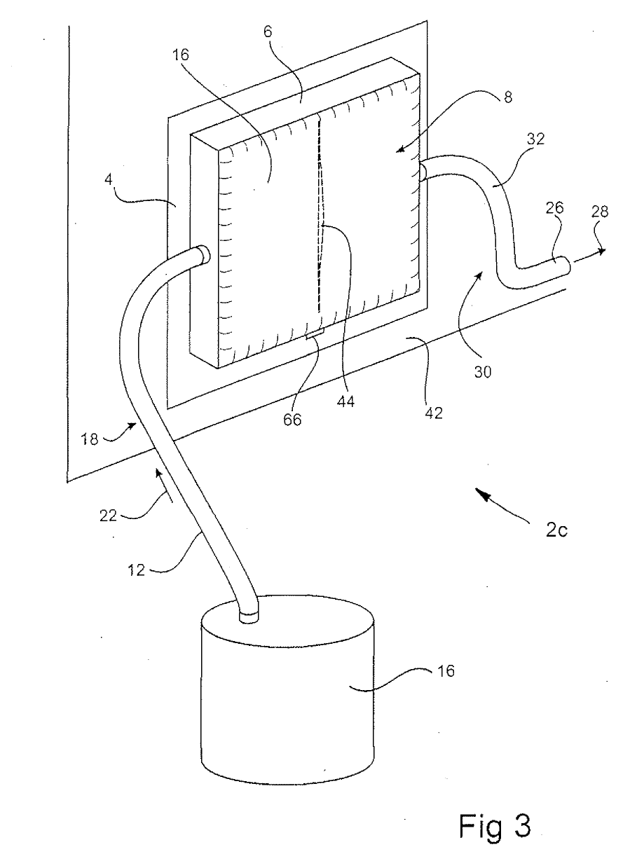

An apparatus 2c in accordance with a further embodiment of the present invention is shown in FIG. 3. The apparatus 2c differs from the apparatus 2b by removal of a portion of the return conduct 14 downstream of the valve 26 so that the vapour is directly exhausted from the chamber 8 through a release assembly 30 comprising a release conduit 32 and release valve 26.

The release valve 26 shown in the embodiments presented in FIGS. 2 and 3 may be a one-way valve, allowing vapour to exhaust to the atmosphere only. Furthermore, the release valve 26 may be switched off so that release of the vapour 28 can be regulated manually and/or electronically.

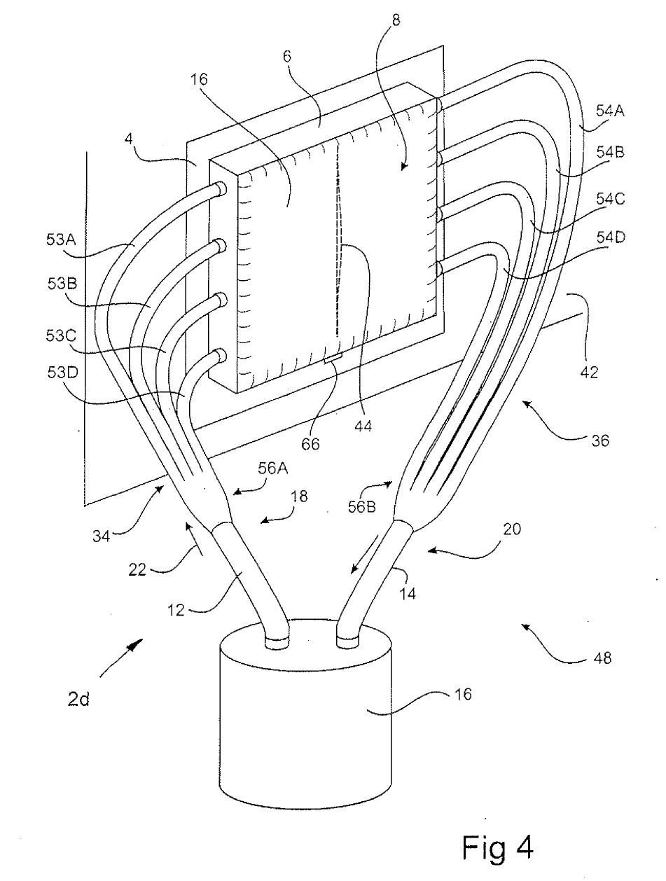

An apparatus 2d, in accordance with a further embodiment of the present invention, is shown in FIG. 4. The apparatus 2d differs from the apparatus 2 by forming the transfer and return sections 18 and 20 to comprise respective manifold distribution systems 56a and 56b coupled between the transfer conduit 12 and return conduit 14 respectively and opposite sides of the chamber 8. The manifold distribution system 56A comprises a plurality of conduits 53A through 53D (hereinafter referred to in general as “conduits 53”). It may be appreciated that the manifold system may comprise any number of conduits.

The conduits 53 may be regularly spaced about the chamber 8 so as to provide an evenly distributed admission of vapour into the chamber 8. Furthermore, return conduits may be placed at the lowest and furthest points from the vapour admission points, to assist in evacuating any leftover dense air that may accumulate in these locations.

Similarly, the manifold distribution system 56B, may also comprise a plurality of return conduits 54A through 54D (hereinafter referred to in general as “conduits 54”). As with the transfer assembly 34, the return assembly 36 is configured so that the conduits 54 are evenly spaced about the chamber 8 so as to receive vapour from said chamber in an evenly distributed manner. Furthermore, the conduits 53 and the conduits 54 positioned relative one another so as to facilitate a flow of vapour through the chamber 8 so that stagnant vapour is minimised and residence time of the vapour in the chamber 8 is maximised thereby maximising heat transfer to the composite material. Hence, the juxtaposition of the conduits 53 and 54 in relation to the chamber 8 is such that a flow of vapour through the chamber 8 is facilitated, thus reducing the ability for the vapour to condense within the chamber 8 or fluid circuit.

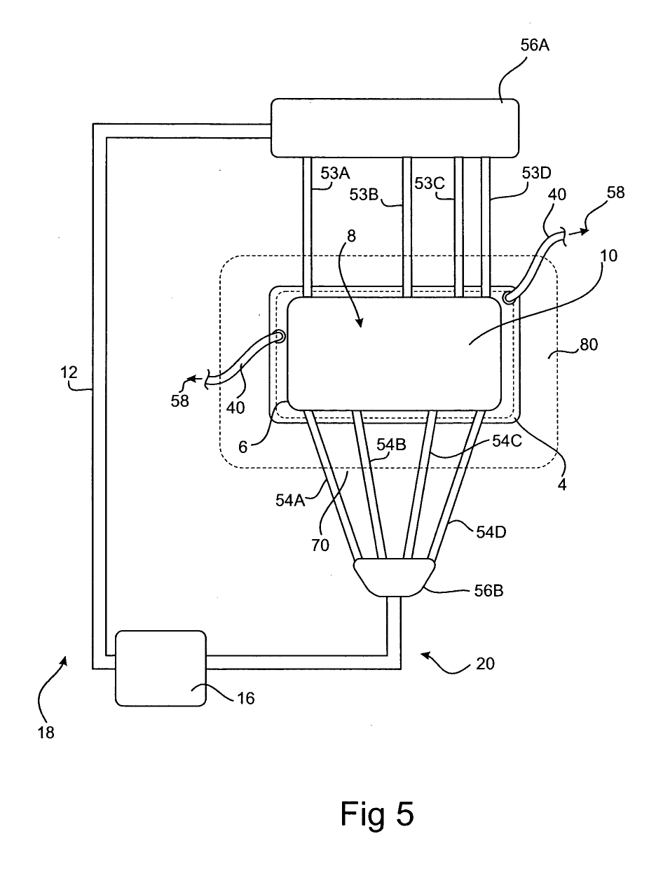

Each of the previous embodiments described incorporate a drainage valve 66 positioned at the lowermost portion of the chamber 8. The drainage valve 66 may be in fluid communication with a pump to pump condensate out of the chamber 8. The embodiments of the present invention shown in FIGS. 1 to 4 and 6 to 8 show the orientation of the chamber 8 such that the vapour flows in a generally horizontal direction across or through the chamber. However, this direction of vapour is not essential and, as shown in FIG. 5, the vapour flow can be in a generally vertical manner by, for example, positioning the conduits 12 and 14 to feed and remove vapour from respective upper and lower edges of the chamber 8. In this way, the return conduits 14 are also aligned in a vertical manner and juxtaposed a lowermost face or surface of the chamber 8 so that any condensate may be drained through the return assembly 36 back to the vapour source 16 by gravity.

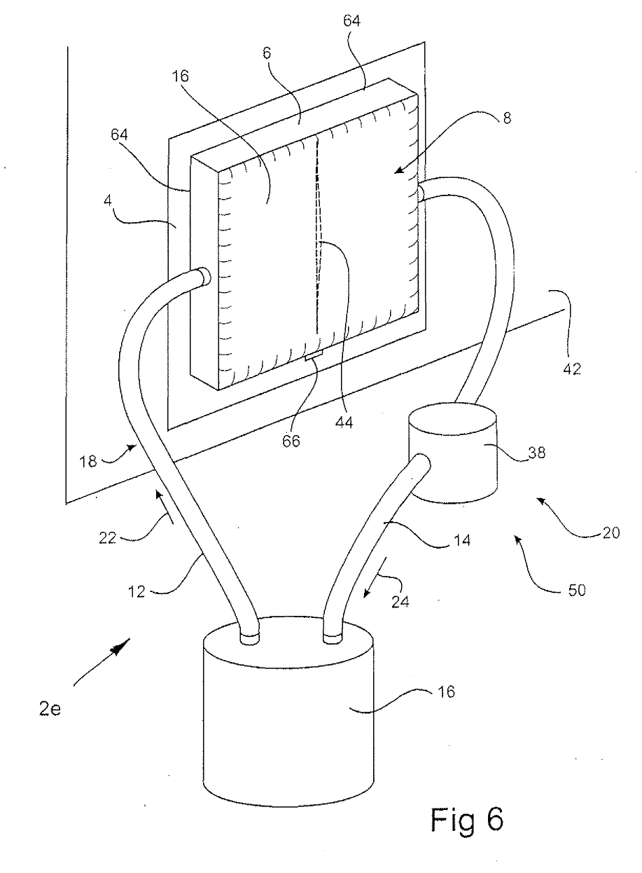

An apparatus 2e in accordance with a further embodiment of the invention is shown in FIG. 6 wherein features common to the apparatus 2, 2b, 2c, and 2d are indicated by the same reference numbers. The main difference between the apparatus 2e and apparatus 2d is the inclusion of a pump 38 in fluid communication with the return section 20 of apparatus 2d. The pump 38 is in fluid communication with the return conduit 14 so that a low pressure (or suction) may be applied within the return section 20 to initiate a flow of vapour from the chamber 8 and assist in controlling or regulating the residence time of the vapour in said chamber. The flow facilitated by the incorporation of pump assists in encouraging a recirculating flow of vapour through the entire circuit. Additionally, in the presence of a recirculating flow, the risk of condensate forming within said chamber is reduced.

Apparatus 2e may also be configured with a transfer assembly 34 and a return assembly 36 as shown in FIG. 4 and FIG. 5. In such an embodiment, the pump 38 will be in fluid communication with the manifold 56B and the vapour source 16. Advantages may be obtained through the use of a vapour distribution network comprising transfer conduits 53 and return conduits 54 juxtaposed chamber 8 and in combination with a pump means 38 by encouraging a recirculating flow through the chamber 8 and establishing an even distribution of heat within the chamber 8.

In some instances where a composite material is to be cured, it is desirable for the composite material to be subject to pressure so as to improve the quality of the cured composite. This is distinct from the curing of the composite material by provision of vapours at atmospheric pressure as described herein. Applying pressure to the composite material is typically carried out by applying a vacuum between a composite material and a layer of material. In this situation, the layer of material is typically known as a vacuum bag and is appropriately sealed around a region of composite material prior to a vacuum being administered. The sealing of the vacuum bag over the composite material upon a work surface effectively defines an internal sealed chamber. When air is evacuated from within the chamber, the layer of material is sucked firmly against the composite material. The pressure exerted by the vacuum bag upon the composite material is proportional to the degree of vacuum that is applied. The pressure of the vacuum bag upon the composite material forces the resin and the fibrous material together, reducing the risk of voids (or air pockets) becoming present during curing of the composite material. Minimalisation of voids is also facilitated by the initial vacuum process.

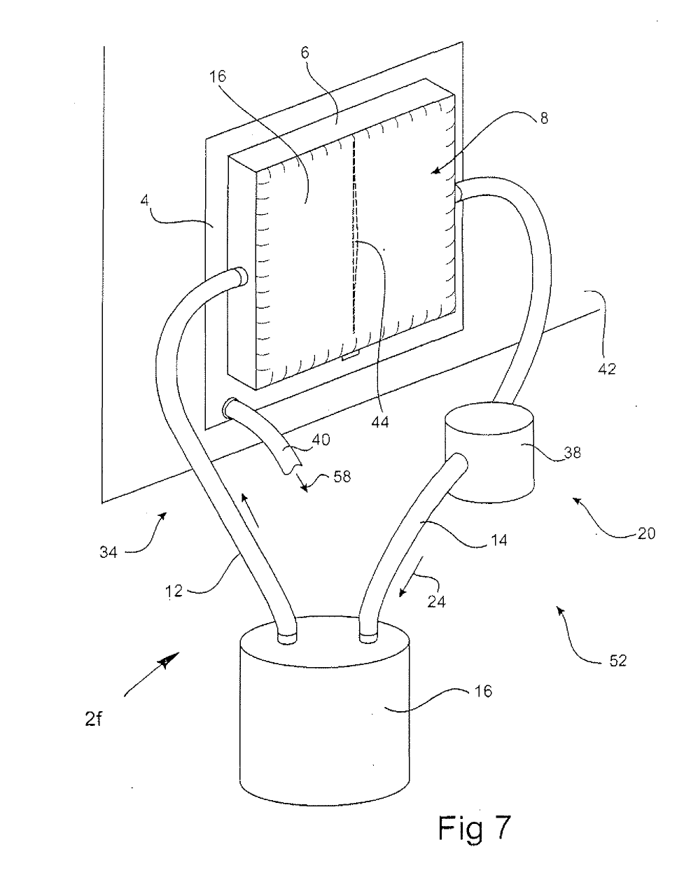

FIG. 7 shows an embodiment of the apparatus 2f in which pressure is applied to the composite in the manner described above. This embodiment is based on the apparatus 2d depicted in FIG. 6, differing only in the addition of a vacuum hose or conduit 40 which is placed in fluid communication between: a space 76 (shown in FIG. 10) defined by the composite material 10 and the overlying first layer of material 4; and, a vacuum pump (not shown). When the vacuum pump is activated, air residing in the space 76 between the composite material and the first layer of material 4 is evacuated through the vacuum hose 40 in a direction 58. Once the vacuum pressure has been applied to the composite material 10, vapour may be admitted into chamber 8 and the curing process may proceed. An identical vacuum hose and vacuum pump arrangement may be incorporated in each of the embodiments of the apparatus 2, 2b and 2c.

An alternative method of applying pressure to the composite material 10 may comprise applying a thermally responsive material such as a layer of “shrink film” material either to the surface of the composite material 10 and/or over the first layer of material 4 and subsequently heating the shrink film material. The shrink wrap material, when subject to heat, begins to shrink and imparts a pressure force over the composite material 10. The heat may be applied by the vapour being supplied to the chamber 8. In some instances, where the structure to be laminated is round, or near round in cross section, a shrink film may be used instead of a vacuum and vacuum bag, to apply the pressure needed during the cure process to achieve the necessary bond strength.

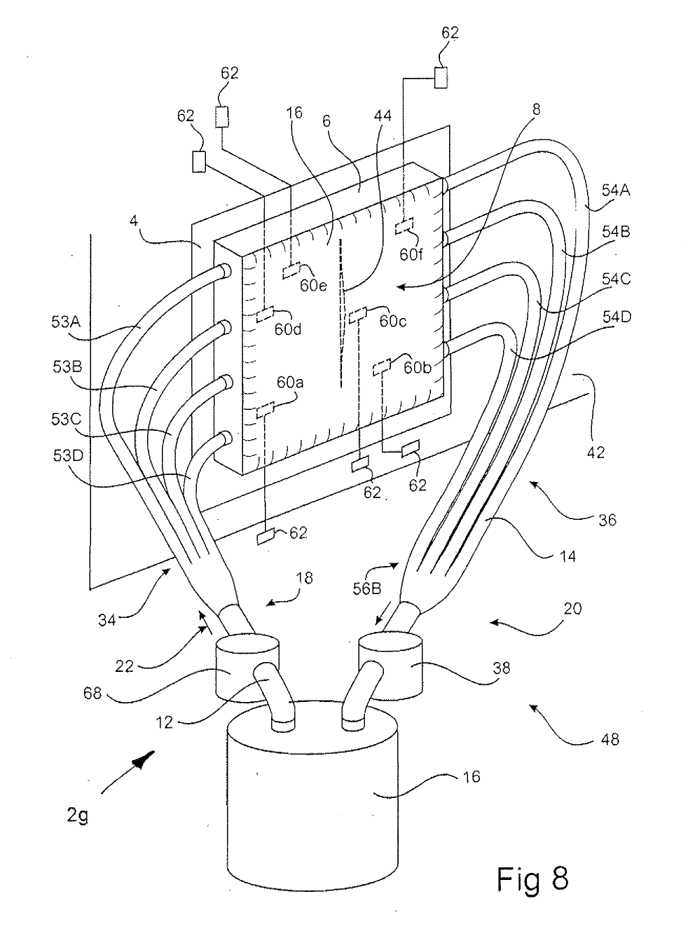

A further embodiment of the apparatus 2g is shown in FIG. 8. Apparatus 2g comprises a combination of many of the features shown in FIGS. 1 through 7, such features being provided with the same reference number as per FIGS. 1 to 7. However, in addition to such features the apparatus 2g further comprises a plurality of temperature-sensing devices or thermocouples (“thermocouples”) 60A through 60F located near the composite material. The recirculation flow rate of the vapour through the circuit can be regulated in accordance with the data obtained from the thermocouples 60A through 60F either individually or collectively. Furthermore, the vapour source 16 can be regulated to alter the thermal characteristics of the vapour in accordance with the temperature data obtained from the thermocouples 60A through 60F. The flow rate of the vapour through the chamber 8 (and/or through the entire circuit) may also be regulated in accordance with analysis and evaluation of the temperature data obtained by thermocouples 60A through 60F.

The data obtained by each thermocouple is communicated, for example, by wire (not shown) or radio transmitter 62, to a central processing unit (CPU) where the data may be stored, processed and evaluated in order to determine how the system parameters (flow rate and/or vapour heat) are to be adjusted.

A suitable temperature sensing device may comprise a bimetallic or thermometallic wire. In the instance where a temperature differential is measured, the actual temperature of the vapour will be generally obtained with reference to ambient temperature. Furthermore, the temperature sensing device may comprise a thermocouple compensating wire which is configured to measure actual temperature or a temperature differential relative to atmospheric temperature.

The temperature sensing devices are generally located in regions of the composite material 10 that will provide the best gauge as to the temperature of the composite in any given time during the curing process. In most instances, the temperature sensing devices will be positioned between the composite material 10 and the surface 80 of the structure 42. Any number of temperature sensing devices may be used at any number of locations throughout the composite material 10. The temperature sensing devices may be sacrificial or of a type that is reusable once curing has completed.

The temperature data obtained by thermocouples 60A through 60f may be used to regulate the dryness factor of the vapour as it recirculates through the circuit

It will be recognised that thermocouples 60A through 60F and the regulation and control means described previously may also be applied to any of the embodiments described herein. In a further embodiment, thermocouples may also be positioned within the chamber 8 to measure temperature of the vapour and communicating this data to the CPU for processing and appropriate regulation. Comparisons between the data obtained from within the chamber 8 and within the composite material 10 may be used to determine the heat transfer efficiency at any stage during the curing cycle.

A further embodiment may comprise the use of pressure transducers positioned at various locations within chamber to monitor the internal pressure. The internal temperature of the chamber 8 may be further controlled by perturbing or adjusting the internal pressure of the chamber 8 so as to maintain optimal heating requirements. As with the temperature sensors, data from the pressure transducers may be communicated to, and processed by, a central processing unit to effect changes in the internal pressure of the chamber 8 by any means known in the art.

All embodiments described herein may also incorporate a second pump 68 located within the transfer conduit 12 of the transfer section 18. The second pump 68 is in fluid communication with the vapour source 16 and the chamber 8 so as to provide a suitable differential in pressure to facilitate the circulation and thus flow of the vapour through the circuit in direction 22. Both first pump 38 and second pump 68 may work either individually or together so as to provide an optimised flow of vapour through the circuit and chamber 8. Either the first pump 38 and/or second pump 68 may be regulated in response to an evaluation of the temperature data obtained from thermocouples 60A through 60F.

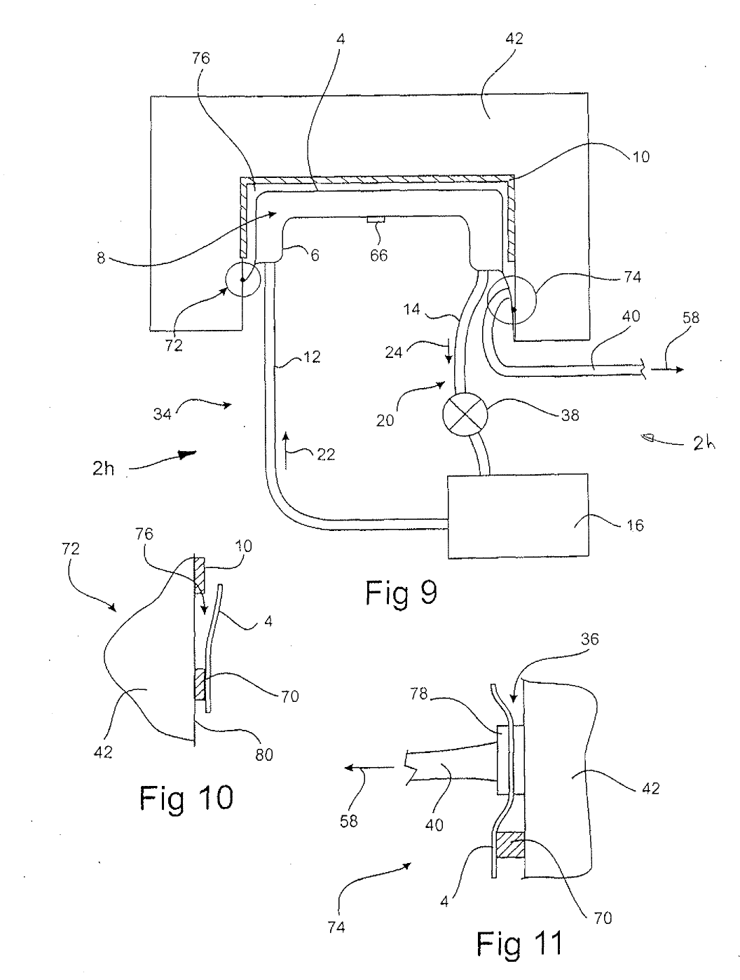

An apparatus 2h in accordance with a further embodiment of the present invention is depicted in a cross-section in FIGS. 9 to 11. Here the apparatus 2h is shown in use curing a composite material 10 on a structure 42 in the form of a channel section to provide reinforcement (which in this instance is a channel section). The composite material 10 overlays an inner portion or surface 80 of the structure 42. A first layer of material 4 is placed over the composite material 10 so that the composite material 10 is physically protected from any moisture during the curing process. A suitable amount of excess material of the first layer 4 is provided around the perimeter of the composite material 10 so that the first layer of material 4 sufficiently fixed or sealed to the surface 80 of the repair region of the structure 42. The first layer of material 4 sealed to the surface of the structure 42 using any known sealant used in the art. Generally, this will comprise a rubbery or tacky adhesive that provides a sufficient barrier and seal so a region or space 76 may be defined between the composite material and the first layer of material 4 when a vacuum is applied.

FIG. 10 shows a cross-section view of the sealing assembly 72 identified in FIG. 9. FIG. 10 shows a sealant 70 establishing the seal or barrier between the surface 80 of the structure 42, thus defining the space 76 encompassing the composite material 10.

FIG. 11 shows a cross-section view of the detail of the vacuum hose connection 74 as identified in FIG. 9. The vacuum hose connection 74 provides a means of evacuating air residing in the space 76 between the first layer of material 4 and the composite material 10. A vacuum hose 40 is connected to a vacuum fitting/nozzle 78. The vacuum fitting/nozzle 78 is suitably configured within an excess portion of the first layer of material 4 so as to expel residing air from space 76 through the vacuum hose 40 when said hose is connected to an appropriate vacuum pump (not shown). Once the air 58 is expelled from the space 76, the first layer of material 4 will be forced against the composite material 10, exerting sufficient force so as to optimise the ratio between the polymer fibres and the resinous matrix material (e.g. epoxy, etc).

The air and/or condensate within the space 76 may be expunged or expelled by applying a first vacuum to the chamber 8 and/or the system. It will be understood that the term vacuum used herein refers to a suction pressure or force applied in such a way so as to evacuate air and/or condensate from a region of space.

In one embodiment of the method, the first vacuum is a high vacuum capable of expunging residual air at a high rate. Alternatively, the air and/or condensate may be expunged from the space 76 by applying a second vacuum that expunges air and/or condensate at a lower rate than the first vacuum. Either the first or the second vacuums may be applied to the return 20 or transfer 12 conduits to expunge the air in the chamber 8 and/or the vapour source 16 before admitting vapour to the chamber 8. Furthermore, residual air and/or condensate from the chamber 8 or system, may involve applying both first and second vacuum alternatively. As an example, it might be necessary to begin with a high suction pressure or force (first vacuum) followed by a lower suction pressure or force (second vacuum) depending on the application and necessity required to ensure that the chamber 8 and/or vapour source is free from air and/or condensate. It will be understood that the converse of the latter may also be applicable pending the circumstance. Furthermore, the latter techniques may be applied to either the return 20 or transfer 12 conduits for causing or facilitating the flow of vapour and/or condensate from the chamber 8 to the vapour source 16, or in some instances, to the atmosphere.

The difference between the first and second vacuum rates may vary. By way of example only, the following vacuum pressure ranges attempt to illustrate the differences between a range of resulting internal pressures:

| State | Internal Pressure (Pa) |
|---|---|
| Low vacuum | 100 to 3 kPa |
| Medium vacuum | 3 kPa to 100 mPa |
| High vacuum | 100 mPa to 100 nPa |
| Ultra high vacuum | 100 nPa to 100 pPa |
| Extremely high vacuum | <100 pPa |

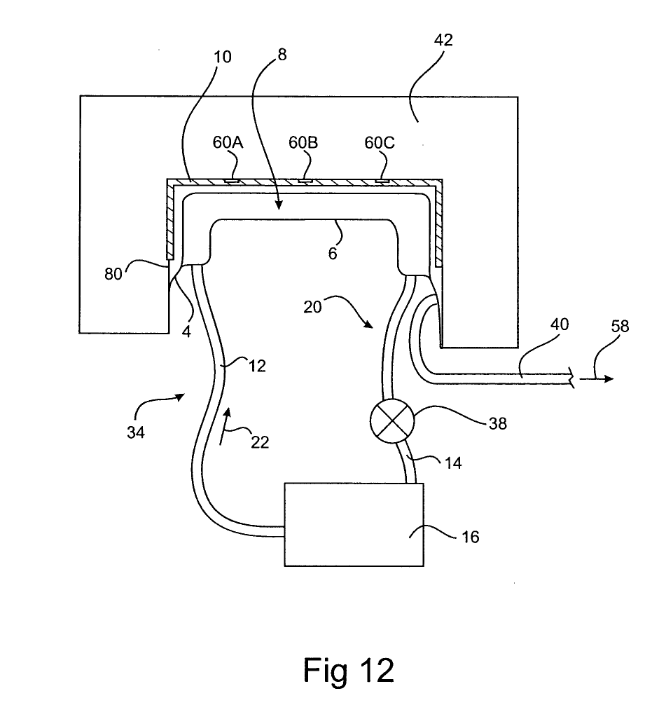

A further embodiment is shown in FIG. 12 where the embodiment shown in FIG. 9 incorporates a plurality of temperature sensing devices 60A through 60C for the purposes of measuring temperature data. The temperature sensing devices 60A through 60C are positioned between the surface 80 of the structure 42 and the composite material 10. The temperature sensing devices 60A through 60C are positioned in such a manner so as to generate a reasonable estimate of the temperature distribution to which the curing composite is being exposed by the recirculating vapour in chamber 8.

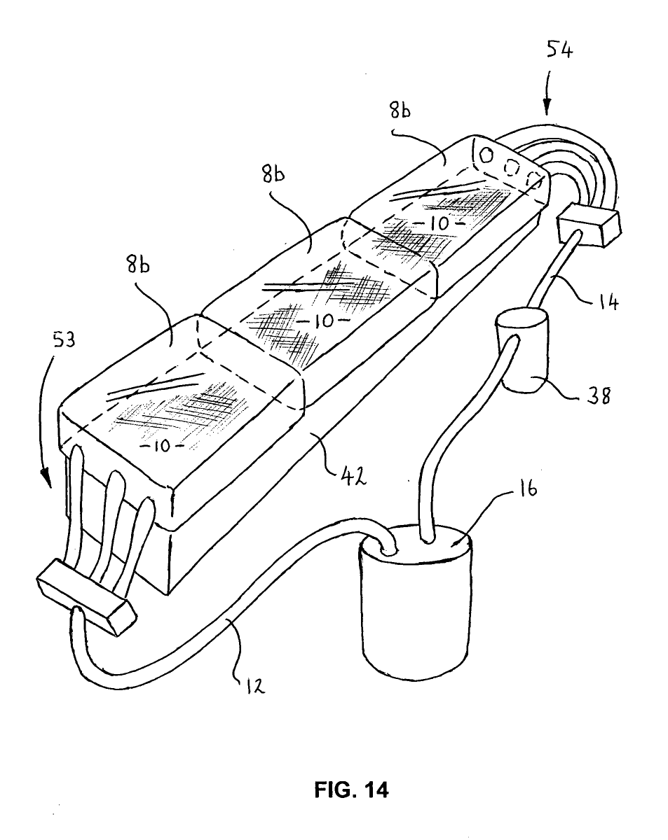

With reference to all the embodiments of the present invention described herein, the chamber 8 may be configured in discrete units 8b that may be placed adjacent or near like units over a composite material 10 of a relatively large length. Each unit 8b will, however, remain in fluid communication with the vapour source by connecting conduits so as to receive vapour for heating the portion of composite material 10 to which the respective unit (chamber 8b) is placed proximate, as shown in FIG. 14. This embodiment of the chamber 8 allows an unlimited, or larger, length of composite structure to be cured by an appropriate number of finite length units configured to be substantially similar to chamber 8.

Any of the embodiments described above may be adapted for integrating within the curing process for any composite material requiring a cure cycle. For instance, it may be that certain components in a structure may require curing at different times relative to other component parts depending on their inter-relationship and relative placement. With a number of localised structural parts to be “cured” in situ, it may be preferable to cure one portion of the structure while leaving an adjacent, or neighbouring, portion to be cured at a later stage. In this instance, it may be necessary to place an insulating barrier between the chamber 8 and the composite 10 that is to be insulated from the heating source. For example, it may be necessary to cure the internal composite bulkheads for a composite yacht in situ before curing the interior skin of the hull shell. The advantage of curing in situ is that the bulkhead, as a critical load bearing component, can be cured in a shape that conforms exactly with the internal shape of the hull. As the bulkhead is constructed internal and transverse to the longitudinal direction of the hull shell, curing the bulkhead in accordance with the previous embodiments described herein will result in a portion of the hull shell interior skin being cured also. To avoid this, an insulating barrier may be placed between the hull shell skin and the chamber 8 either side of the bulkhead at locations where the chamber 8 may overlay or effect to otherwise transfer heat to the hull shell skin. The bulkhead(s), as a component part, can thus be cured in isolation from the hull yet within the structure itself. Subsequently, the bulkhead, once cured, may be cured with the hull skin, providing a chemical bond rather than a mechanical bond, which would otherwise occur if the bulkhead was merely “glued” to the cured hull shell (as is often the case). Use of an insulating barrier with the present invention thus provides a substantial degree of versatility for in-situ curing.

It will be appreciated by those skilled in the art that the embodiments of the present invention described herein enables elevated temperature cure without the creation of significant infrastructure, allowing efficient and economic in situ repair of ships, boats, aircraft, automotive equipment, farm equipment, wind turbines, blades, trains and many other forms of industrial equipment.

As previously indicated, any embodiment of the current invention described herein may be used to create new structures for use in creating other structures. For example, the framework for a concrete pad may first be layered up and cured before positioning in place and pouring concrete, with the advantage being that the framework remains as a permanent fixture as opposed to having to be removed.

Resin infusion, or like infusion technology, may be used where a vacuum is applied between the composite material 10 and the first layer of material 4. Resin infusion is a method known in the art used to draw resin through a composite material using a uniquely configured vacuum source. The applied vacuum draws the resin, from a resin source, through the composite material until the entirety of said compilation is adequately saturated with resin. An advantage of resin infusion methods, and associated technology, is that the optimum resin content or optimum resin-fibre ratio can be obtained in cases where pre-resin impregnated material is not, or cannot, be used.

Numerous variations and modifications will suggest themselves to persons skilled in the relevant art, in addition to those already described, without departing from the basic inventive concepts. All such variations and modifications are to be considered within the scope of the present invention, the nature of which is to be determined from the foregoing description.

The claims defining the invention are as follows:

1-31. (canceled)

32. An apparatus for the forming or curing of a fibre-reinforced polymer composite material comprising:
first and second layers of material arranged so as to define to chamber for overlying a fibre-reinforced polymer;
a vapour source;
a fluid communication path having:
(i) a transfer section in fluid communication with the vapour source and the chamber; and,
(ii) a return section in fluid communication with said chamber and said vapour source,
the vapour source being configured for supplying vapour to the chamber at substantially atmospheric pressure.

33. The apparatus according to claim 32, wherein said communication path is configured to emit vapour and/or condensate of said vapour to the atmosphere.

34. The apparatus according to claim 32, wherein said transfer section of said fluid communication path comprises at least one transfer conduit to provide vapour from said vapour source to said chamber.

35. The apparatus according to claim 34, wherein said return section of said fluid communication path comprises at least one return conduit so as to return said condensate and/or said vapour to said vapour source.

36. The apparatus according to claim 32, wherein said second layer is affixed to said first layer to define said chamber.

37. The apparatus according to claim 32, wherein said second layer is heat sealed to said first layer so as to define said chamber.

38. The apparatus according to claim 32, wherein said first and second layers comprise an air-tight material.

39. The apparatus according to claim 32, wherein said first and second layers comprise an airtight material of limited extensibility.

40. The apparatus according to claim 32, wherein said first or second layers comprises of at least:
(a) a flexible material;
(b) a rigid material;
(c) a thermally responsive material.

41. The apparatus according to claim 32, wherein a vacuum is established between said first layer and said polymer.

42. The apparatus according to claim 35, wherein said fluid communication path comprises a first pump means coupled to said return conduit and configured to pump condensate and/or said vapour from said chamber to said vapour source.

43. The apparatus according to claim 42, wherein said fluid communication path comprises a second pump means coupled to said transfer conduit pump condensate and/or said vapour from said vapour source, to said chamber.

44. The apparatus according to claim 32, wherein at least one temperature sensing device is positioned adjacent or proximal said polymer or within said communication path to measure temperature.

45. The apparatus according to claim 32, wherein flow rate of vapour through said fluid communication path is regulated by at least one temperature measurement obtained from said at least one temperature sensing device.

46. The apparatus according to claim 32, wherein the temperature of said vapour within said fluid communication path is regulated by at least one temperature measurement obtained from said temperature sensing device.

47. The apparatus according to claim. 32, wherein the Dryness factor of said vapour within said communication path is regulated by at least one temperature measurement obtained from said temperature sensing device.

48. The apparatus according to claim 35, wherein said transfer and return conduits and said chamber are relatively juxtaposed one another so as to encourage a flow of said vapour through said chamber.

49. A method for the forming or curing of a fibre-reinforced polymer composite comprising the steps of:
(i) laying up an uncured fibre-reinforced polymer;
(ii) overlaying said polymer with a first flexible layer of material;
(iii) overlaying said first flexible layer of material with a second layer of flexible material so as to define a chamber therebetween;
(iv) filling said chamber with a heated vapour from a vapour source in fluid communication with said chamber; and
(v) returning at least a portion of said vapour and/or condensate of said vapour to said vapour source.

50. The method according to claim 49, further comprising the step of applying a vacuum, to a region between said polymer and said first layer of material.

51. The method according to claim 49, further comprising the step of providing a transfer conduit in fluid communication with said vapour source and said chamber whereby said vapour is transferred from the vapour source to said chamber.

52. The method according claim 51, further comprising the step of providing a return conduit in fluid communication with said vapour source and said chamber to return said vapour and/or condensate of said vapour to said vapour source.

53. The method according to claim. 49 further comprising the step of applying a first vacuum between the first and second layer to remove air from the chamber and/or vapour source prior to admitting said vapour.

54. The method according to claim 52, further comprising the step of applying a second vacuum via said return conduit for inducing or facilitating a flow of said vapour and/or condensate of said vapour from said chamber to said vapour source.

55. The method according to claim 54 further comprising the step of applying the second vacuum after application of the first vacuum, via said return conduit for inducing or facilitating a flow of said vapour and/or condensate of said vapour from said chamber to said vapour source.

56. The method according to claim 54, further comprising the step of applying the second vacuum within said transfer conduit for inducing or facilitating a flow of said vapour and/or condensate of said vapour source to said chamber.

57. The method accordion to claim 54 wherein the first vacuum is greater than the second vacuum.

58. The method according to claim 45, further comprising the step of applying pressure to said vapour in said transfer conduit to change the thermal characteristics of said vapour.

59. The method according to claim 49, wherein the step of laying up of an uncured fibre-reinforced polymer is conducted in situ.

60. The method according to claim 49 wherein step (v) comprises:
returning all said vapour and/or condensate to the atmosphere.
